(19) United States
(12) Patent Application Publication
(10) Pub. No.: US 2013/0105874 A1
(43) Pub. Date: May 2, 2013

(54) SEMICONDUCTOR DEVICE, MEMORY CARD, DATA PROCESSING SYSTEM, AND METHOD OF MANUFACTURING SEMICONDUCTOR DEVICE

(71) Applicants: Takeo FUJII, Tokyo (JP); Masao TAGUCHI, Tokyo (JP)

(72) Inventors: Takeo FUJII, Tokyo (JP); Masao TAGUCHI, Tokyo (JP)

(73) Assignee: ELPIDA MEMORY, INC., Tokyo (JP)

(21) Appl. No.: 13/338,945

(22) Filed: Dec. 28, 2011

(30) Foreign Application Priority Data
Oct. 28, 2011 (JP) 2011-237067

(51) Int. Cl. H01L 27/088; H01L 21/336

(52) U.S. Cl. 257/300; 438/257; 257/316; 257/E21.422; 257/E27.06

(57) ABSTRACT

A semiconductor device includes a gate electrode provided on a channel region in a semiconductor material layer having one type through a second insulating film; a capacitor electrode portion integrally formed with the gate electrode on the gate electrode; and a first electrode laterally surrounding the capacitor electrode portion through a first insulating film.

### BACKGROUND OF THE INVENTION

1. Field of the Invention

The present invention relates to a semiconductor device, a memory card, a data processing system, and a method of manufacturing a semiconductor device.

2. Description of the Related Art

Nonvolatile memory devices which have floating gates and which are electrically erasable and recordable have been incorporated in diverse systems and have been widely used. Among them, so-called NAND flash memory has become a mainstream since it can lower the bit cost.

As a representative configuration of a NAND flash memory, a device, on which each memory cell having a floating gate that is provided between a control gate and a channel is mounted, is known, and for example, is disclosed in US 2010/0291766 A1. First, a line and space pattern, which becomes a floating gate in future, is formed by patterning a conductive layer provided on a surface of a silicon substrate through a tunnel insulating film, and then a trench device isolation is formed by etching the silicon substrate using the line and space pattern as a mask and embedding an insulation material. Then, another conductive layer is formed through the medium of an inter-gate insulating film, and patterned into a line and space pattern of a control gate, which is extended in a direction that is orthogonal to the pattern of the floating gate. The floating gate formed in the line pattern is etched using the line and space pattern of the control gate as a mask to obtain a rectangle-shaped floating gate. Further, by ion-injecting impurities having an opposite conductivity to the silicon substrate onto an active region of the surface of the silicon substrate that is exposed in this process, a source/drain region, which is aligned to an edge of the control gate, i.e., to an edge of the floating gate, can be formed. As described above, since the memory cell can be formed using two orthogonal fine line and space patterns, the process has been widely used in general.

On the other hand, in the case of the NAND flash memory, by giving a control signal to the control gate, the potential of the capacitively coupled floating gate is controlled to a desired potential and thus read and write operations are performed. Because of this, it is necessary to set the ratio of a capacitance value between the control gate and the floating gate to a capacitance value between the floating gate and the silicon substrate to a desired value. With the progress in miniaturization of the memory cell, the height of the floating gate becomes very high, and this causes problems in that the coupling capacitance between the floating gates is increased and the potential of the floating gate of the memory cell that is selected by written information of an adjacent memory cell is significantly changed. For this, US 2010/0291766 A1 discloses a technique of reducing the coupling capacitance between the floating gates through providing of a cavity in the floating gate. Further, JP 2009-289902 A discloses a technique of providing a control gate to surround the periphery of the floating gate that is composed of a first conductive film and a third conductive film by forming the first conductive film that becomes the floating gate electrode, providing a hole for connecting to the first conductive film on a second conductive film for the formed control gate through an insulating layer, and then embedding an interposed dielectric film (IPD film) in a side surface of the hole and embedding the third conductive film in the hole. This technique can also reduce the coupling capacitance between the floating gates.

However, although US 2010/0291766 A1 discloses the technique of reducing the opposite surface area between the floating gates of the adjacent cells through forming of the cavity in the floating gate, the processing technique for forming the cavity is complex and difficult, and thus the completed shape is not uniform. Further, if the miniaturization progresses, it becomes difficult to provide the cavity in order to maintain the mechanical strength.

Further, in 2011 3^{rd} IEE International Memory Workshop (IMW) pp 18-21 “25 nm 64 Gb 130 mm2 3 bpc NAND Flash Memory”, a technique of reducing the coupling capacitance between floating gates of adjacent cells through providing a cavity in part of an insulating film between floating gates of adjacent cells is disclosed. However, the technique of processing uniform cavity with good reproducibility is difficult. If the miniaturization proceeds, the gap between the floating gates of the adjacent cells becomes narrow, and it is difficult to secure a cavity at a predetermined interval, resulting in reduction of the effect.

In JP 2009-289902A, in the floating gate, a gate electrode portion and a capacitor electrode portion formed between the control gates on the gate electrode portion are separately formed, and a process of electrically connecting both portions is essential. Since the number of bits of a memory cell on a semiconductor chip is very large, the presence of such electrical connections in the floating gate becomes a major factor that reduces the yield unfavorably. Further, in order to provide such electrical connections, it is necessary to form an IPD film in the hole and to remove the IPD film on the bottom of the hole by etching, and thus the IPD film that is exposed to the side surface of the hole is damaged. Since this is unbearable in practical use as it is, a sacrificial IPD film is firstly formed and an IPD film is newly filled in a slit formed by removing the sacrificial IPD film after forming a third conductive layer. However, there are problems in that it is very difficult to fill a good-quality film in such a narrow slit, and if void is formed, the capacitance value is significantly changed. Further, if the sacrificial IPD film on the bottom of the hole is insufficiently removed, a yield loss occurs due to an abnormal electrical resistance or open inferiority of the electrical connections.

### SUMMARY

According to one embodiment of the present invention, there is provided a semiconductor device, which includes a gate electrode provided on a channel region in a semiconductor material layer having one conduction type through a second insulating film; a capacitor electrode portion integrally formed with the gate electrode on the gate electrode; and a first electrode laterally surrounding the capacitor electrode portion through a first insulating film. According to another embodiment of the present invention, there is provided a method of manufacturing a semiconductor device, which includes forming a hole in a layer formed on a semiconductor material layer having one conduction type; forming a first electrode through forming of a film that includes a conductive material on an inside wall of the hole; forming a first insulating film on an inside wall of the first electrode; and embedding a gate electrode in the hole in contact with the first insulating film.

According to one embodiment of the present invention, coupling capacitance between floating gates of adjacent cells can be reduced without reductions of production yield and reliability, and potential of the floating gate can be controlled in a state of reducing influence from written information in the adjacent cell so that the operating margin extremely increases.

### BRIEF DESCRIPTION OF THE DRAWINGS

The above features and advantages of the present invention will be more apparent from the following description of certain preferred embodiments taken in conjunction with the accompanying drawings, in which:

FIG. 1(a) is a plan view of a semiconductor device according to an exemplary embodiment of the present invention. FIG. 1(b) is a cross-section view taken along line A-A′. FIG. 1(c) is a cross-sectional view taken along line B-B′.

FIGS. 2 to 9 and 11 to 12 are views illustrating a process for manufacturing a semiconductor device of FIG. 1, in which each of sub-drawings (a) is a plan view, each of sub-drawings (b) is a cross-sectional view taken along line A-A′, and each of sub-drawings (c) is a cross sectional view taken along line B-B′.

FIG. 10 illustrates a modified example of the process shown in FIG. 9, in which each of FIG. 10(a) is a plan view, each of FIG. 10(b) is a cross-sectional view taken along line A-A′, and each of FIG. 10(c) is a cross sectional view taken along line B-B′.

FIGS. 13 to 16 are views illustrating a process for manufacturing a semiconductor device according to another exemplary embodiment of the present invention, in which each of sub-drawings (a) is a plan view, each of sub-drawings (b) is a cross-sectional view taken along line A-A′, and each of sub-drawings (c) is a cross sectional view taken along line B-B′.

FIGS. 17 and 18 are views illustrating another modified exemplary embodiment of a process for manufacturing a semiconductor device according to the present invention, in which FIGS. 17(a) and 18(a) are plan views, FIGS. 17(b) and 18(b) are cross-sectional views taken along line A-A′, and FIGS. 17(c) and 18(c) are cross sectional views taken along line B-B′.

FIG. 19 is a block diagram illustrating the schematic configuration of a NAND flash memory according to an embodiment of the present invention.

FIG. 20 is a schematic diagram illustrating the configuration of a memory card using a NAND flash memory according to the present invention.

FIG. 21 is a block diagram illustrating the configuration of a data processing system using a NAND flash memory according to the present invention.

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

The fundamental configuration of the invention includes a gate electrode comprising a gate electric portion functioning as a gate electrode and a capacitor electrode portion that constitutes a capacitor and is integrally formed with the gate electrode portion, and a conductive layer arranged between adjacent gate electrodes. This configuration can significantly reduce coupling capacitance between the adjacent gate electrodes. In an embodiment, since the capacitor electrode portion that is integrally formed with the gate electrode portion is laterally surrounded by a first electrode, the coupling capacitance between the adjacent gate electrodes can be reduced, and the coupling capacitance between the gate electrode and the first electrode can be increased. In the semiconductor device according to the invention, the gate electrode portion and the capacitor electrode portion are integrally formed into a gate electrode, and the gate electrode does not include the structure that electrically connects the conductive layers as disclosed in JP 2009-289902 A. Accordingly, the semiconductor device does not cause a yield loss due to an abnormal electrical resistance or open inferiority of a connection portion.

A method of manufacturing a semiconductor device according to the invention can easily provide a structure in which the side surface of the capacitor electrode portion of the gate electrode is surrounded by the first electrode by providing a hole on a layer formed on an upper side of a channel region and laminating a first electrode layer, an insulating layer, and a gate electrode layer in order inside the hole. According to the invention, a very fine structure can be obtained very easily. In particular, since a sidewall film that is formed by depositing a conformal conductive layer on the inside wall of the hole is used as the first electrode layer, the first electrode can be formed so that the capacitor electrode portion of the gate electrode is surely surrounded by a very thin conductive layer. According to JP 2009-289902 A, the hole is provided in the second conductive layer that becomes the control gate, the insulating layer and the capacitor electrode portion are formed on the inside wall of the hole, a wiring is formed through patterning of the second conductive layer by a lithography technique, and the control gate is formed. Since the hole and the wiring pattern are misaligned, it is not possible to reduce the width of the control gate outside the hole to the limit. Further, even in order to lower the electrical resistance value of the wiring, the width of the control gate of the outside of the hole cannot be thinned. Accordingly, it is necessary to widen the width of the control gate, and it causes a problem during miniaturization.

Hereinafter, preferred embodiments of the invention will be described in detail with reference to the accompanying drawings.

First, a semiconductor device according to an embodiment of the invention will be described in detail using a NAND flash memory on which NAND flash memory cells are mounted as an example.

### Exemplary Embodiment 1

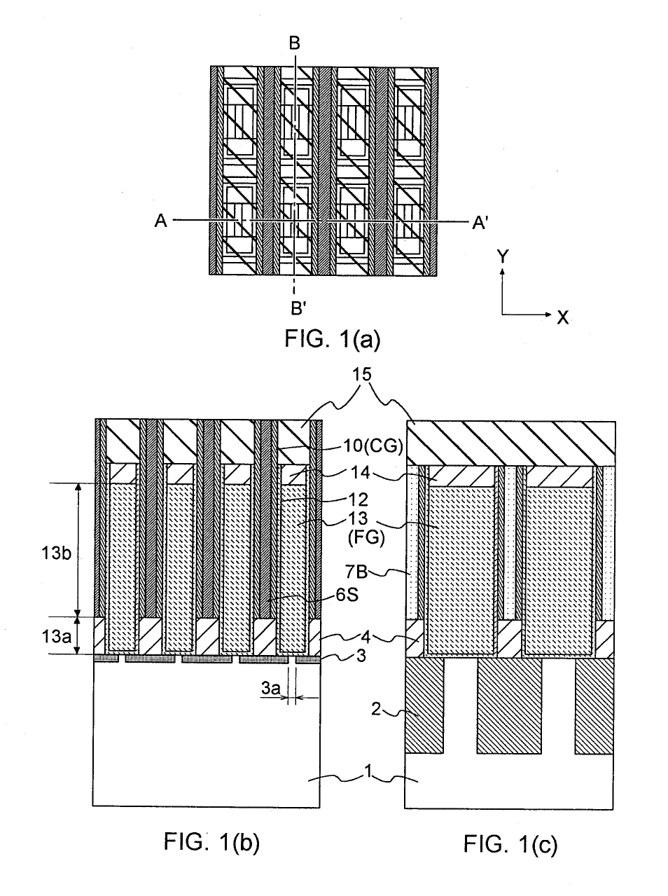

FIG. 1(a) is a plan view of a semiconductor device according to an exemplary embodiment of the present invention, FIG. 1(b) is a cross-section view taken along line A-A′, and FIG. 1(c) is a cross-sectional view taken along line B-B′. In FIGS. 1(a) to 1(c), NAND flash memory cells of 4×2 bits are illustrated. A device isolation region that is extended in X direction is provided on a main surface of silicon substrate 1, and four NAND flash memory cells, each of which includes floating gate (FG) 13, control gate (CG) electrode 10 that is the first electrode, and source/drain impurity diffusion layer 3, are connected in series on an active region that is positioned between the device isolation regions 2. The FG 13 is a columnar electrode made of a conductive material such as polycrystalline silicon, has gate electrode portion 13a and capacitor electrode portion 13b that is integrally formed with the gate electrode portion 13a, and is formed on an upper side of slit 3a that is provided on the source/drain impurity diffusion layer 3 through insulating film 12 (tunnel insulating film). The side surface of the capacitor electrode portion 13b of the FG 13 is surrounded by cylindrical CG electrode 10 that is made of a conductive material such as polycrystalline silicon or metal through the insulating film 12 (inter-gate electrode insulating film). The CG electrode 10 is insulated from the silicon substrate 1 by insulating layer 4 formed from a silicon oxide film or the like. The capacitor portion that is configured by the CG electrode 10, the FG 13 and the insulating film 12 is formed in a hole that is defined by isolation sidewall film 6S, and the capacitor portions are insulated from each other by the isolation sidewall film 6S. The CG electrode 10 is formed by the conductive film provided in the form of a thin sidewall on the inside wall of the hole that is defined by the isolation sidewall film 6S, the insulating film 12 is formed on the inside wall thereof, and the FG 13 is formed by the columnar electrode embedded in the hole on the inside thereof. On an upper portion of the FG 13, an embedded insulating layer 14 is provided. On the embedded insulating layer 14, control gate driving signal line 15 that is composed of a conductive layer and extended in Y direction is provided, and the line 15 is connected to the CG electrode 10. The control gate driving signal line 15 is insulated from the FG 13 by the embedded insulating layer 14.

As described above, in this embodiment, since the side surface of the capacitor electrode portion 13b of the FG 13 having the gate electrode portion 13a integrally formed with the capacitor electrode portion 13b is laterally surrounded by the CG electrode 10 so that the conductive layer is arranged between the adjacent FGs 13, the capacitance coupling between the FGs 13 of the adjacent cells is kept very small in comparison to the NAND flash memory cell structure in the related art. As a result, since it becomes possible to precisely perform potential control of the floating gate without being affected by the written data of the adjacent cell, a wide operating margin is obtained, and especially when writing multi-level information, a stable operation becomes possible. The gate electrode portion 13a and the capacitor electrode portion 13b of the FG 13 are integrally formed, and the FG 13 does not include a structure that electrically connects the conductive layers. Further, since the control gate is formed in a sidewall shape and can be very thin, it is advantageous in miniaturization of the memory cell. As the tunnel insulating film and the inter-gate electrode insulating film, films which have the same composition and are deposited in the same process are used. Further, since the insulating film 6S between the control gate driving signal lines 15 is formed in a sidewall shape and has little bowing shape, an insulating film having little variation is obtained. As described, the CG electrode 10, the insulating film 12, and the FG 13 are formed on the inside wall of the hole that is positioned between the isolation sidewall films 6S, and the conductive material is embedded in a groove which is positioned between the isolation sidewall films 6S and is extended in Y direction to form the control gate driving signal line 15.

Next, a method of manufacturing a semiconductor device according to the Exemplary Embodiment will be described in detail.

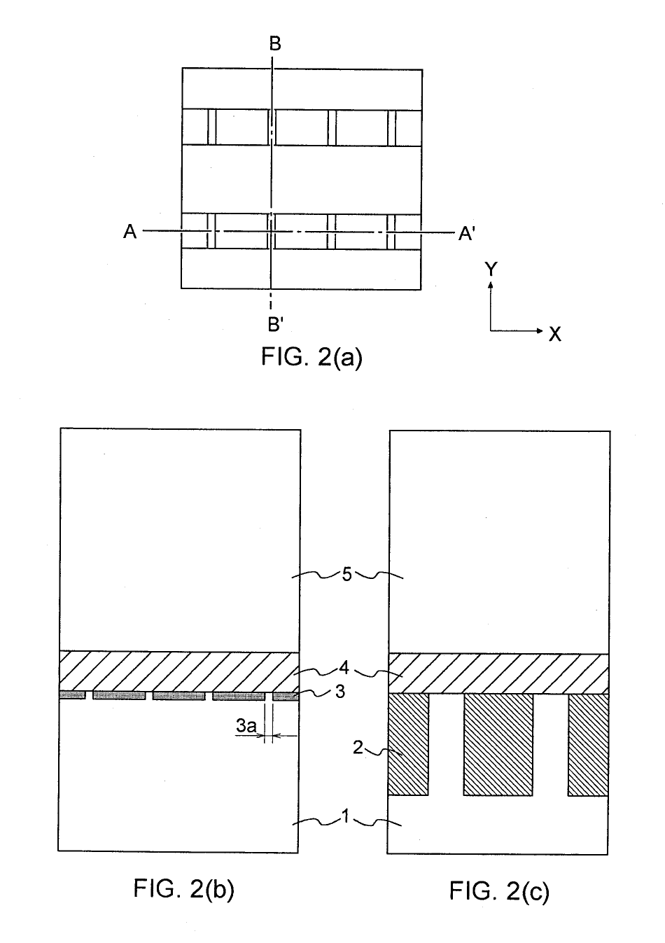

FIGS. 2 to 12 are views illustrating a process for manufacturing a semiconductor device according to Exemplary Embodiment 1 of the invention. Among them, FIGS. 2(a) to 12(a) are plan views, FIGS. 2(b) to 12(b) are cross-sectional views taken along line A-A′, and FIGS. 2(c) to 12(c) are cross-section views taken along line B-B′.

According to the process for manufacturing a semiconductor device according to this embodiment, as illustrated in FIGS. 2(a), 2(b), and 2(c), a groove is first formed on an element isolation forming region of the surface of p-type silicon substrate 1, and element isolation region 2 is formed by embedding an insulating film such as a silicon oxide film. Then, n-type impurity diffusion layer 3 is formed through ion-injecting of n-type impurities such as arsenic into the surface of an active region. In a place where a floating gate is arranged later on, slit 3a is provided on the n-type impurity diffusion layer 3, and the impurity diffusion layer 3 is separately positioned between the slits so as to function a source and a drain. The impurity diffusion layer 3 is formed before the floating gate is formed. For example, the width of slit 3a is 10 nm. This is a value that is narrower than a channel length of a MOS transistor of a peripheral circuit. Thereafter, insulating layer 4 and material layer 5 that is made of a different material from the insulating layer 4 are deposited in order. For example, the insulating layer 4 and the material layer 5 can be a silicon oxide layer and a polycrystalline silicon layer, respectively. The material layer 5 can be made of an insulating material such as a silicon nitride layer. If an etching ratio is insufficient, a thin etching stopper layer (not illustrated) can be provided between the insulating layer 4 and the material layer 5.

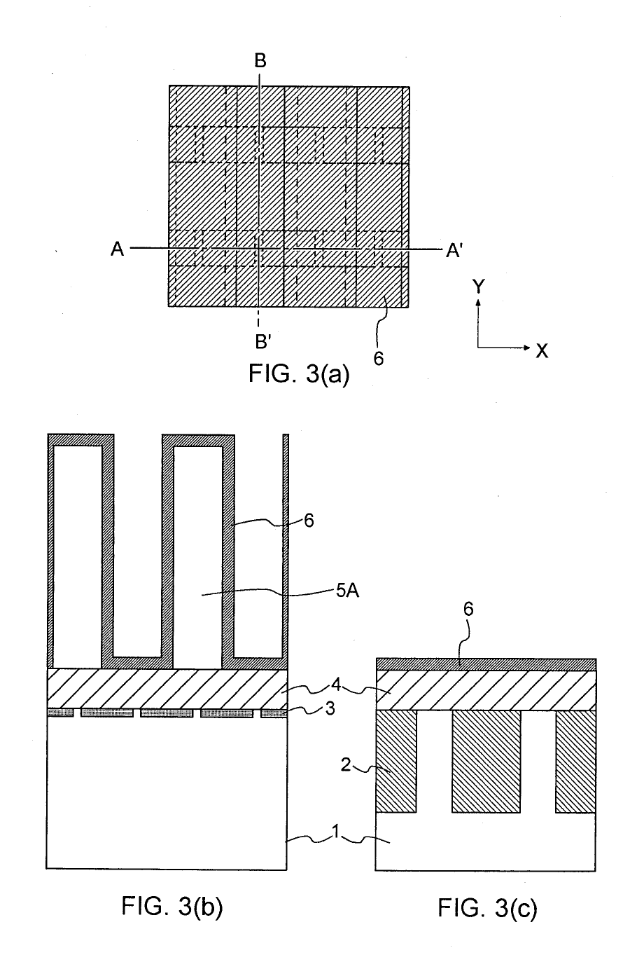

As illustrated in FIGS. 3(a), 3(b), and 3(c), pattern 5A that is extended in the Y direction is formed by selectively etching the material layer 5 using a photolithography technology and a dry etching technology. The pattern 5A is alternately arranged just above the slit 3a, that is, with a pitch that is twice the pitch of the memory cell in the X direction. Here, since a groove pattern having a relatively wide open width is formed, the groove can be formed into little bowing shape. If necessary, dimensional adjustment can be performed by adding dry etching or wet etching.

Then, for example, silicon nitride film 6 is deposited on the whole surface.

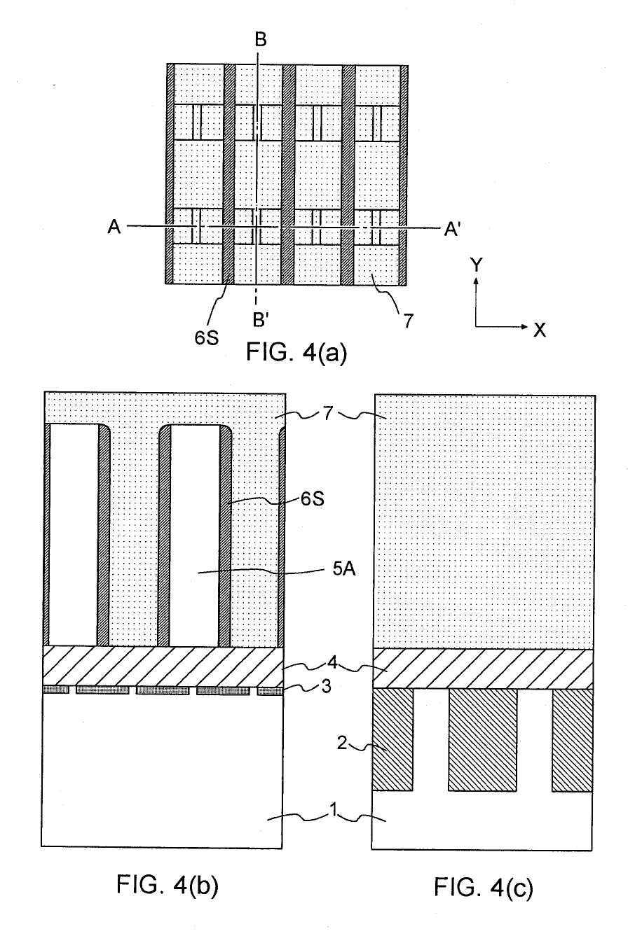

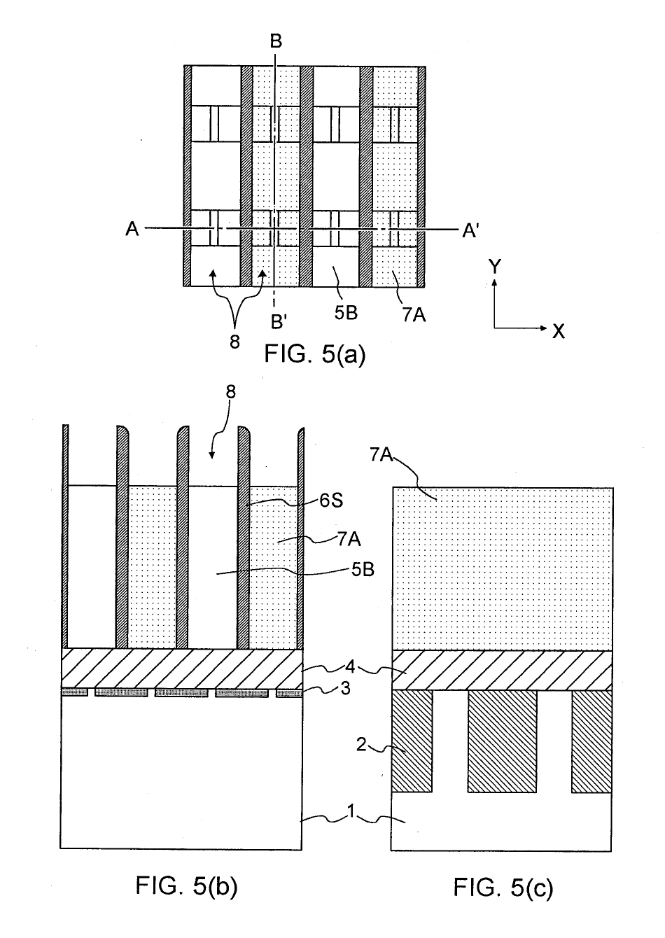

As illustrated in FIGS. 4(a), 4(b), and 4(c), by performing anisotropic etching back after conformally depositing the silicon nitride film 6, isolation sidewall film 6S that is extended in the Y direction is formed while leaving only the side surfaces of the pattern 5A. Then, a concave portion that is positioned between the patterns 5A is embedded by depositing polycrystalline silicon 7 on the whole surface, and then the surface is flattened using a CMP technology. Further, as illustrated in FIGS. 5(a), 5(b), and 5(c), the pattern 5A and the polycrystalline silicon 7 are etched back by dry etching to a height that is lower than an upper portion of the isolation sidewall film 6S for a predetermined height to form pattern 5B and polycrystalline silicon 7A. Accordingly, groove 8 for forming a control gate driving signal line that is extended in the Y direction is formed. The groove for forming the control gate driving signal line can be provided on the material layer 5 by a typical lithography technology instead of the isolation sidewall film 6S. In this case, a hard mask layer is provided on the material layer 5.

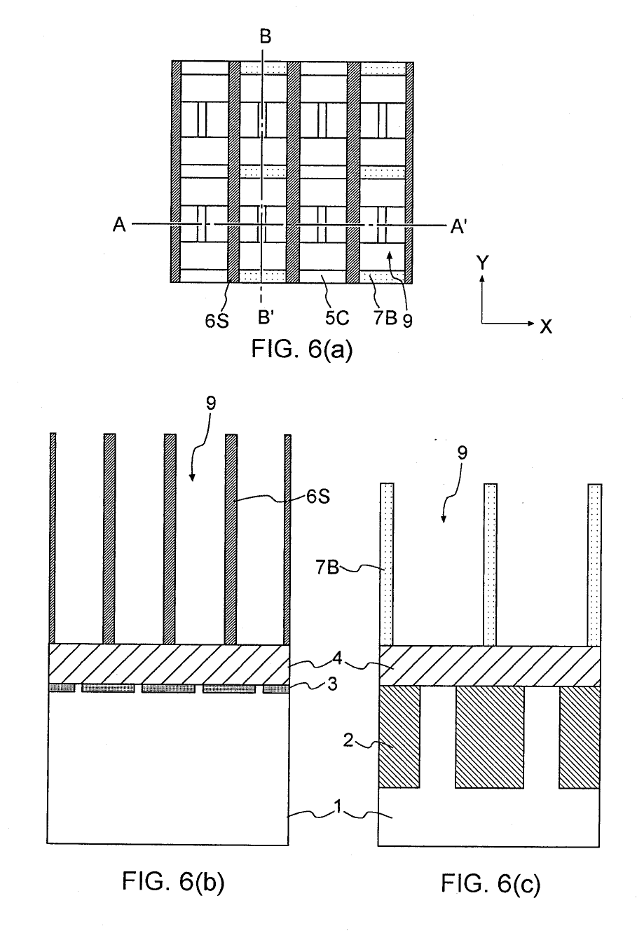

Then, as illustrated in FIGS. 6(a), 6(b), and 6(c), a hole 9 for forming a memory cell is formed by selectively removing the pattern 5B and the polycrystalline silicon 7A by etching using a photoresist pattern or a hard mask pattern (not illustrated) that is extended in the X direction as a mask. Two sides of the hole 9 in the X direction are made of a silicon nitride layer (isolation side surface film 6S), and two sides in the Y direction are made of polycrystalline silicon (pattern 5C and polycrystalline silicon 7B).

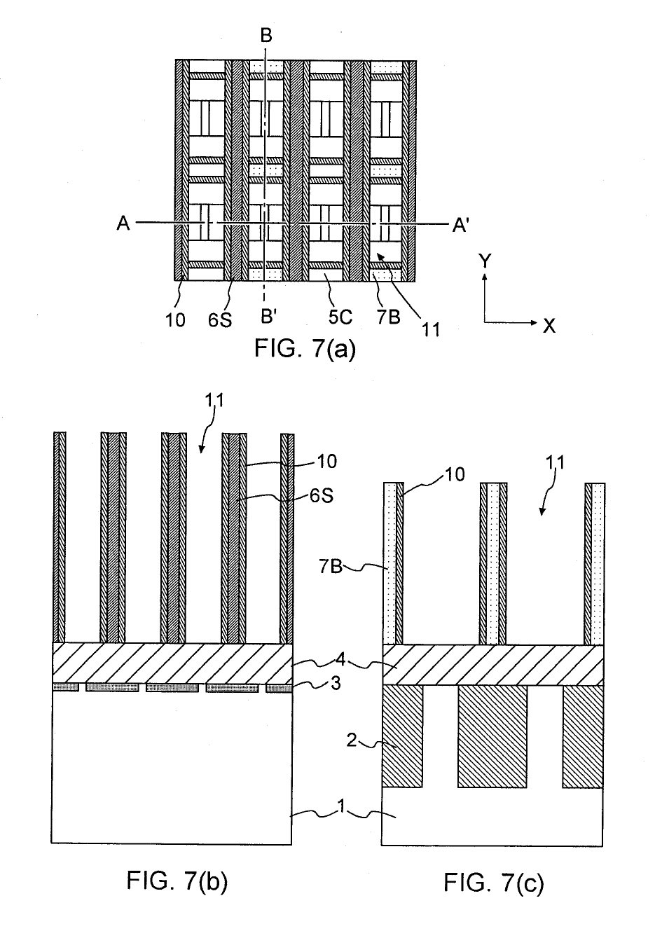

Then, as illustrated in FIGS. 7(a), 7(b), and 7(c), a sidewall film that is composed of a conductive material is formed on an inside wall of the hole 9. As the material, for example, polycrystalline silicon is used. By performing anisotropic etching back after depositing a thin conductive film on the whole surface, the sidewall film for CG electrode 10 is obtained. In this way, the CG electrode 10 that is in a very thin cylindrical shape is formed. The hole that is surrounded by the CG electrode 10 is called hole 11.

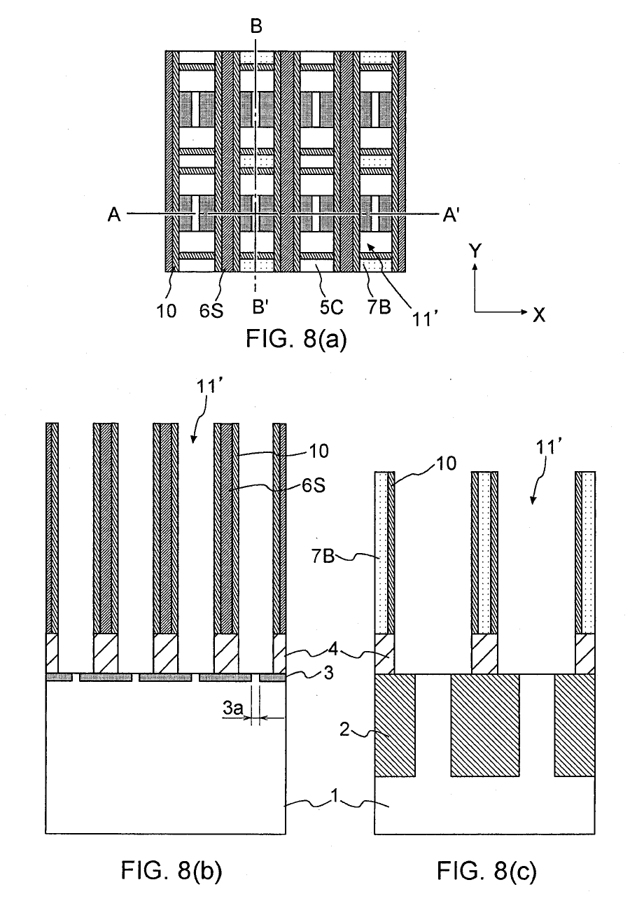

Then, as illustrated in FIGS. 8(a), 8(b), and 8(c), the surface of the silicon substrate 1, which includes a region in which the slit 3a that is positioned between the impurity diffusion layers 3 is formed, is exposed by selectively removing the insulating layer 4 that is exposed to the bottom of the hole 11 by etching using the CG electrode 10 as a mask. At this time, it is not necessary for the whole slit 3a to be exposed, but at least a part thereof is exposed. The hole after the etching is called hole 11′.

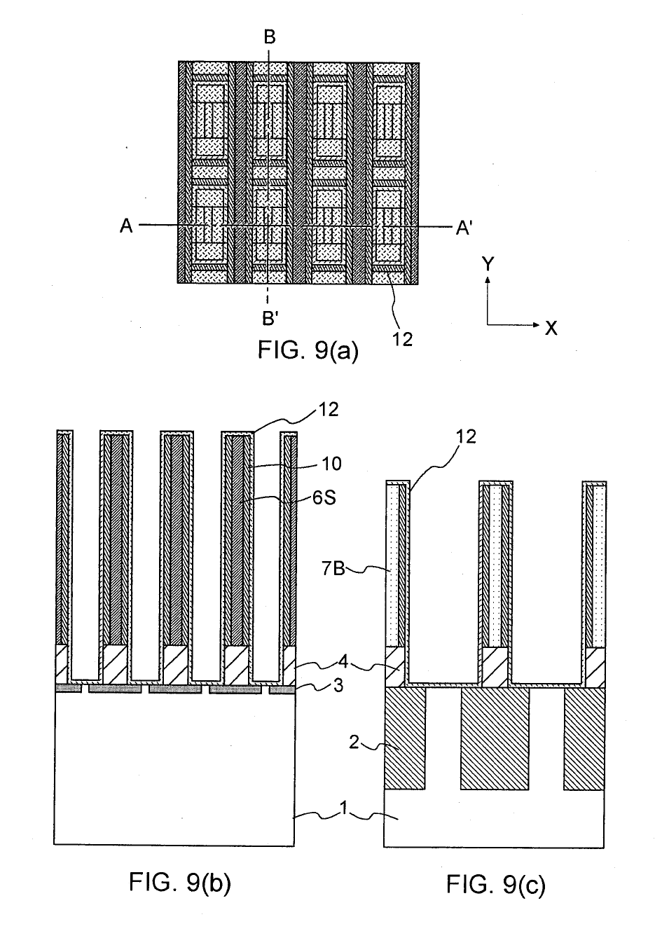

Then, as illustrated in FIGS. 9(a), 9(b), and 9(c), thin insulating film 12 is deposited on the whole surface. The thin insulating film 12 which is formed on the surface of the silicon substrate 1 that is exposed to the bottom of the hole 11′ is a portion that functions as a tunnel insulating film when electrons are injected into the floating gate that is formed on the insulating film 12 later. Further, the thin insulating film 12 that is formed on the side surfaces of the hole 11′ becomes an inter-gate electrode insulating film that forms a capacitor between the floating gate to be formed later and the CG electrode 10 that is remained as a sidewall of the hole 11′. That is, dielectric films, which determines two capacitance values that determine the capacitance ratio that is necessary to operate as a flash memory device, i.e., a capacitance value between the CG electrode 10 and the floating gate, and a capacitance value between the floating gate and a channel region of the silicon substrate 1, are all thin insulating film 12, and are simultaneously deposited in the same process. In the memory cell structure in the related art, it was impossible to deposit such insulating films in the same process. In this embodiment, on the other hand, since the dielectric films are simultaneously deposited in the same process, it is easy that not only the film structure (composition) but also the characteristic of the film that is caused by the variation or fluctuation of the manufacturing process becomes equal to each other. Accordingly, a desired capacitance ratio is obtained with good reproducibility by managing the shape or dimensions (bottom area or height of the hole) of the hole 9 for forming the memory cell. As a result, since it becomes possible to precisely perform potential control of the floating gate, a wide operating margin is obtained, and especially when writing multiple data, a stable operation becomes possible. As the method for depositing the thin insulating film 12, the technique that is known as the method of forming a tunnel insulating film in the conventional art is applicable. For example, there is an example in which a silicon nitride film is deposited by an LP-CVD method, and then dry oxidation process is performed. In this case, the insulating film 12 includes even the side surface of the insulating layer 4 that reaches from the surface of the silicon substrate 1 to the side surface of the hole 11′ as illustrated in FIGS. 8(b) and 8(c), and becomes a continuous film.

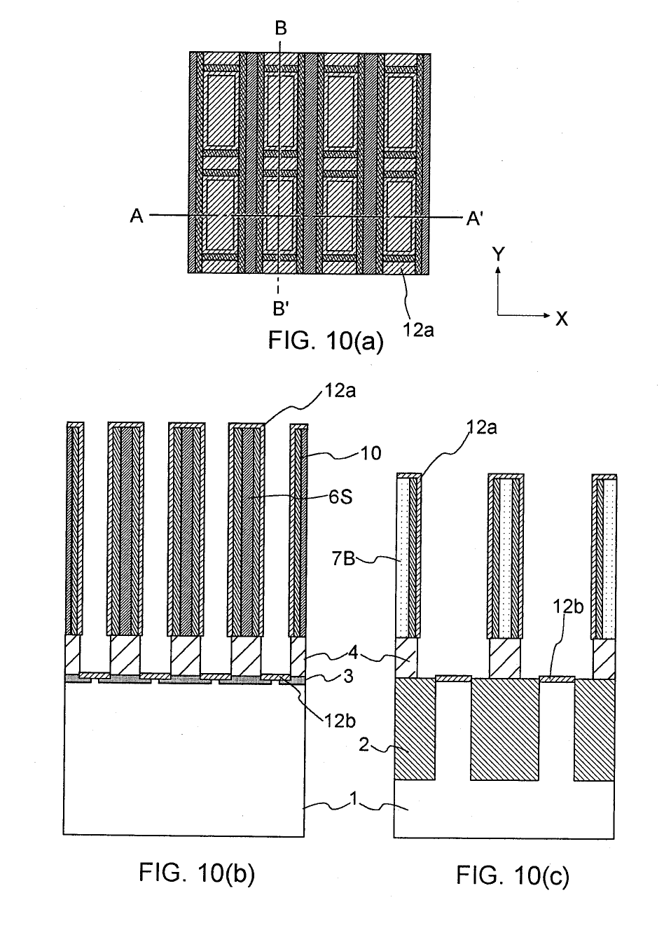

On the other hand, in the case where the CG electrode 10 is formed of polycrystalline silicon, there is a method of forming SiON by oxynitriding the surfaces of the CG electrode 10 and the silicon substrate 1 through performing of heat-treatment under NO ambient. In this case, the reaction rates on the polycrystalline silicon surface and on the monocrystalline silicon substrate surface are approximately equal to each other, and the films having almost the same characteristics are obtained. Further, in this case, the insulating film 12, as illustrated in FIG. 10, is composed of a first insulating film 12a that is formed on the side surface of the CG electrode and a second insulating film 12b that is formed on the surface of the silicon substrate 1, which are not continuous. Incidentally, the surface of 5C and 7B which are made of polycrystalline silicon is oxynitrided in the same manner, and the surface of the isolation sidewall film 6S that is made of silicon nitride is slightly oxidized, while the insulating layer 4 and the element isolation region 2 which are made of silicon oxide are less affected.

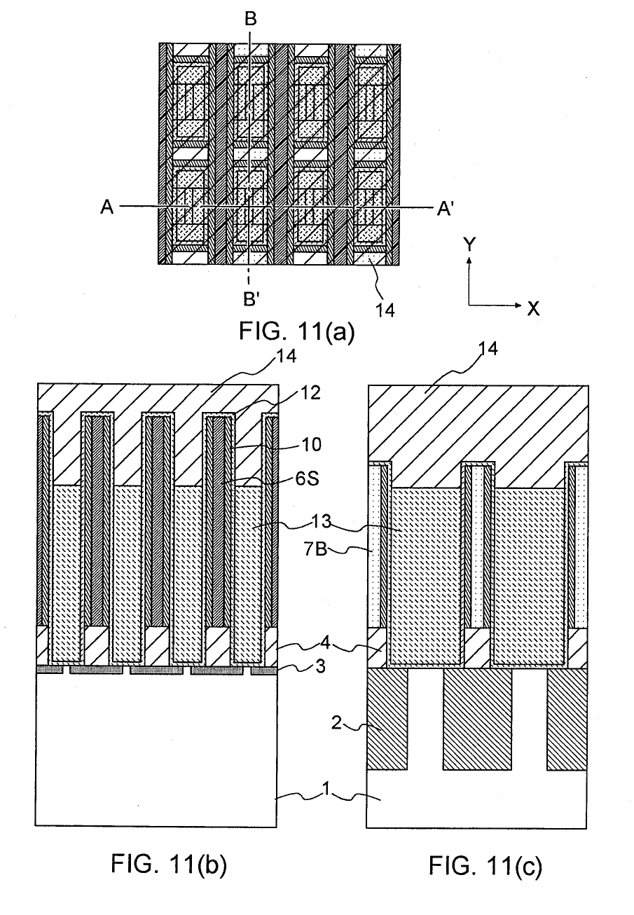

Then, as illustrated in FIGS. 11(a), 11(b), and 11(c), a conductive material is embedded in the hole 11′. For example, after depositing the polycrystalline silicon, the FG 13 is formed by etching back the polycrystalline silicon. In this case, the surface of the polycrystalline silicon is etched back to be slightly lower than the top of the hole 11′. Thereafter, an insulating material such as a silicon nitride film is deposited on an upper portion of the FG 13 to form embedded insulating layer 14.

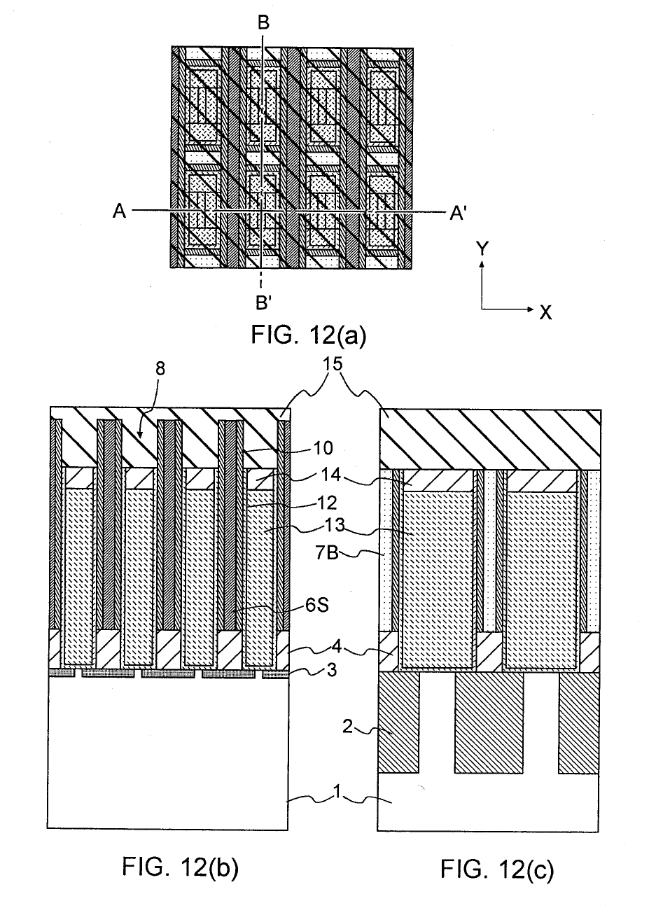

Then, as illustrated in FIGS. 12(a), 12(b), and 12(c), by etching back the embedded insulating layer 14 and the insulating film 12, the upper surface of the CG electrode 10 is exposed while leaving the embedded insulating layer 14 on the upper portion of the FG 13.

Then, a barrier metal and a seed layer (not illustrated) are deposited in the groove 8 for forming the control gate driving signal line, and then the conductive material is embedded. By removing the conductive material on the surface until the isolation sidewall film 6S is exposed by CMP, the control gate driving signal line 15 is formed and is connected to the CG electrode 10 to complete a device as illustrated in FIGS. 1(a), 1(b), and 1(c). It is possible to form the control gate driving signal line 15 simultaneously with a metal wiring (not illustrated) that is formed by a Damascene process of a peripheral circuit region.

According to the manufacturing method in this embodiment, impurities that become the source/drain are introduced into the active region that is formed on the silicon substrate, and the hole for forming the NAND flash memory cell is formed on the bottom portion of the groove for forming the control gate driving signal line by selectively etching the bottom of the groove for forming the control gate driving signal line that is defined by the isolation sidewall film extended in the Y direction using the line and space pattern extended in the X direction. The control gate electrode is formed by forming into a sidewall that is made of a conductive material in a hole. After the surface of the active region that is formed on the silicon substrate is exposed by selectively removing by etching the bottom portion of the hole that is surrounded by the control gate electrode, the floating gate in which the gate electrode portion and the capacitor electrode portion are integrally formed is formed by embedding the conductive material in the resulting hole after simultaneously forming thin insulating film on the exposed surface of the silicon substrate active region and the surface of the control gate electrode. From the above, the NAND flash memory cell is obtained. Further, by embedding the conductive material in the groove for forming the control gate driving signal line that is on an upper side of the NAND flash memory cell, the control gate driving signal line is completed.

In this embodiment, unlike the NAND flash memory cell in the related art in which the impurity diffusion layer that becomes the source/drain is formed through self-alignment of the gate electrode using the gate electrode as a mask, the impurity diffusion layer that becomes the source/drain is first formed, and then the control gate and the floating gate are formed, so that the shape of the impurity diffusion layer that becomes the source/drain can be independently determined and adopted regardless of the planar shape of the control gate or the floating gate. Further, since the process of ion-injecting a narrow region that is positioned between the very high floating gates is not required, the problem of the increased electrical resistance of the source/drain region, which is caused by the non-introduction of the sufficient impurities onto the surface of the silicon substrate, can be eliminated.

The slit 3a of the impurity diffusion layer 3 shown in FIG. 1(b) can be made to be narrower than the interval of the source/drain impurity diffusion layer of a MOS transistor (not illustrated) that constitutes the peripheral circuit. In the case of the NAND flash memory device, since a plurality of memory cell transistors is connected in series and a driving voltage is given to both ends of the serial circuit, the voltage that is applied between the source/drain impurity diffusion layers of one memory cell decreases. Accordingly, the interval of the source/drain impurity diffusion layers can be significantly reduced in comparison to that of the MOS transistor that constitutes the peripheral circuit. On the other hand, since the difference in current between cases where the memory cell is in an On-state and is in an Off-state becomes large by decreasing the interval of the source/drain impurity diffusion layers, the operating margin when data is read by a sense amplifier widens.

The method of manufacturing a NAND flash memory cell according to this embodiment has features in that the control gate is first formed, and then the conductive layer for forming the floating gate is deposited later. Further, after forming the groove for forming the control gate driving signal line and the hole for forming the NAND flash memory cell on the material layer formed on the silicon substrate, neither of the lithographic process of forming a pattern using a photo mask and the process of forming electrical contact between the conductive layers is included in the process of depositing the conductive material film for the control gate electrode on the inside wall of the hole to the process of completing the floating gate. These completely eliminate the problems caused by the misalignment and the possibility of the occurrence of the abnormal electrical resistance or open inferiority caused by the intervening layer between the conductive layers. Further, fewer manufacturing processes, the entire silicon substrate deposition process, and the entire etching process mean that the processes are very easy.

Since the control gate electrode is formed of a sidewall film and the film thickness can be thinned to the utmost limit as long as the thickness satisfies the electrical characteristic, the planar occupation area of the control gate electrode becomes smallest. This is very suitable for miniaturization of the NAND flash memory cell.

The method of manufacturing a NAND flash memory cell according to this embodiment has features in that the tunnel insulating film between the floating gate and the channel and the inter-gate electrode insulating film between the floating gate and the control gate are deposited in the same process.

Although the potential of the floating gate is controlled by the potential given to the control gate and the ratio of the capacitance value between the floating gate and the channel to the capacitance value between the floating gate and the control gate, in the related art, the tunnel insulating film and the inter-gate electrode insulating film cannot be deposited in the same process. By performing deposition in the same process, it becomes possible to make the tunnel insulating film and the inter-gate electrode insulating film have almost the same composition or almost the same structure, and it becomes possible to dramatically reduce the fluctuation and variation of the capacitance ratio. This is particularly advantageous in storing multi-level information in a one-bit memory cell.

The NAND flash memory cell according to this embodiment has features in that the control gate electrodes of the adjacent NAND flash memory cells in the X direction are respectively connected to different control gate driving signal lines, and are electrically isolated by the isolation sidewall film. Further, the control gate driving signal lines are also electrically isolated in the X direction by the isolation sidewall film. The position of the side surface of the control gate driving signal line and the position of the outer wall of the control gate electrode of the NAND flash memory cell are self-aligned to match each other. More specifically, the groove for forming the control gate driving signal line that constitute a first line and space pattern and is extended in the first direction (Y direction) is formed, and then the hole for forming the NAND flash memory cell is formed using a second line and space pattern that is extended in the second direction (X direction) that crosses the first direction in a region where both space patterns overlap. At this time, different materials are selected as the materials that form the line portion and the space portion of the first line and space pattern. Further, the line portion is formed using the sidewall film itself. As another manufacturing method, it can include forming a hard mask layer on the line portion of the first line and space pattern, removing an under layer by etching using the hard mask as a mask to form the groove for forming the control gate driving signal line, and then forming the hole for forming the NAND flash memory cell by using the second line and space pattern in the region where both space patterns overlap. Here, the hard mask can be formed into a sidewall film. Since the position of the side surface of the control gate driving signal line and the position of the outer wall of the control gate electrode of the NAND flash memory cell match each other, and the possibility of misalignment between both parties or misalignment of edge positions by the etching are completely eliminated, it is not required to provide a pattern margin, and it is very suitable for miniaturization of the NAND flash memory cell. Further, the miniaturization becomes possible up to the limit from the viewpoint of the electrical characteristic such as the leakage current and reliability, regardless of the resolution limit of the lithographic technology, by applying the sidewall film. Therefore, it is very suitable for miniaturization of the NAND flash memory cell. In general, a pattern of the semiconductor device having a fine memory cell matrix is formed as a pattern that is close to the resolution limit using the periodicity of the pattern. At this time, since the periodicity of the end of the memory cell matrix is interrupted, the pattern width may be changed or a pattern collapse may occur. Further, a problem for the cross-sectional shape may occur such as the etching process of a fine deep groove may easily cause the bowing shape. In such a case, among the above-described manufacturing methods, the problems can be suppressed by forming the line portion of the first line and space pattern using the sidewall film itself. In particular, since the control signal for the control gate is required to supply a high voltage, a place in which the insulating film is locally thin may cause problems of reliability. In contrast, the thickness of the isolation sidewall film is relatively easy to control.

Then, modified examples of this embodiment will be described.

### Exemplary Embodiment 2

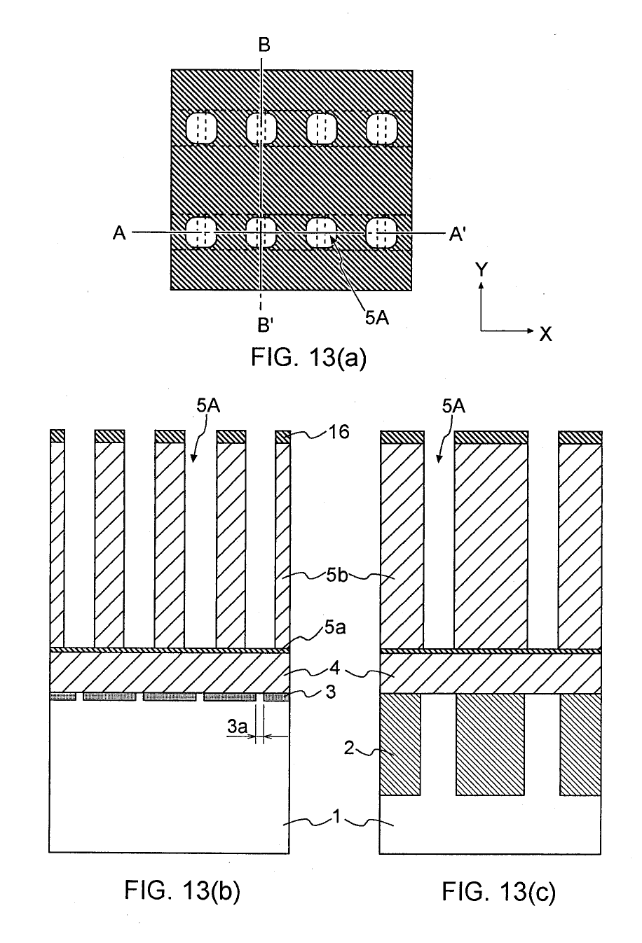

FIGS. 13 to 16 are views illustrating a process for manufacturing a semiconductor device according to Exemplary Embodiment 2 of the invention.

Among them, FIGS. 13(a) to 16(a) are plan views, FIGS. 13(b) to 16(b) are cross-sectional views taken along line A-A′, and FIGS. 13(c) to 16(c) are cross-sectional views taken along line B-B′.

After the process illustrated in FIG. 2, a hole 17 for forming a NAND flash memory cell is formed on each slit 3a formed on a source/drain impurity diffusion layer 3 by selectively removing a material film 5 by etching as illustrated in FIG. 13. For example, a hole that forms a smooth curve due to a roundish corner of a pattern edge is formed on the material layer 5 using a photo mask on which a hole pattern, for example, having a shape of a rectangle, other polygons, a circle, or an ellipse is arranged. Here, as the material layer 5, an etching stopper film 5a that is a silicon nitride film and a core layer 5b that is a silicon oxide film are formed, and a hard mask layer 16 composed of a silicon nitride film is formed on the core layer 5b.

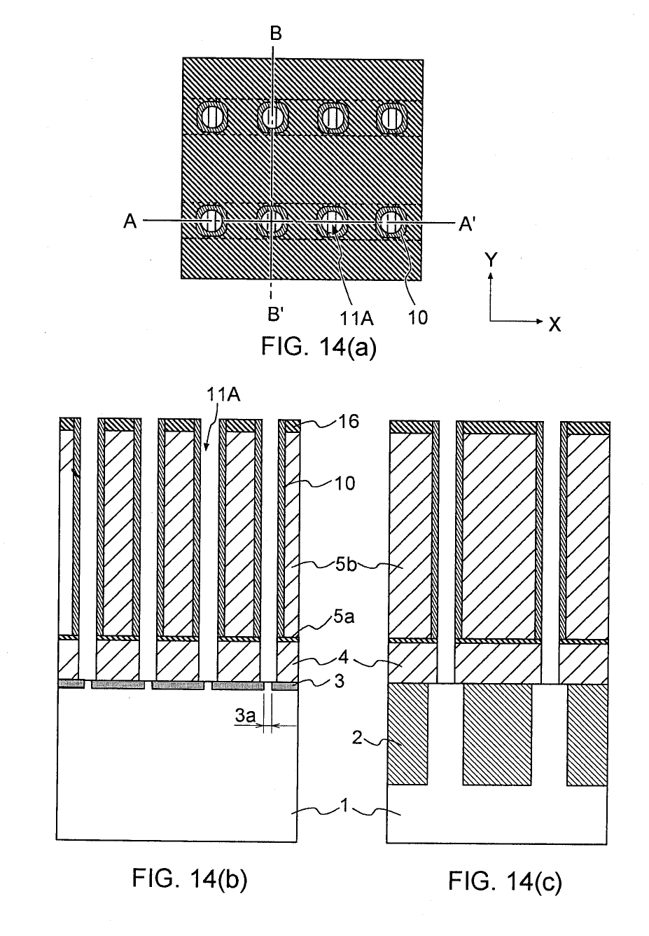

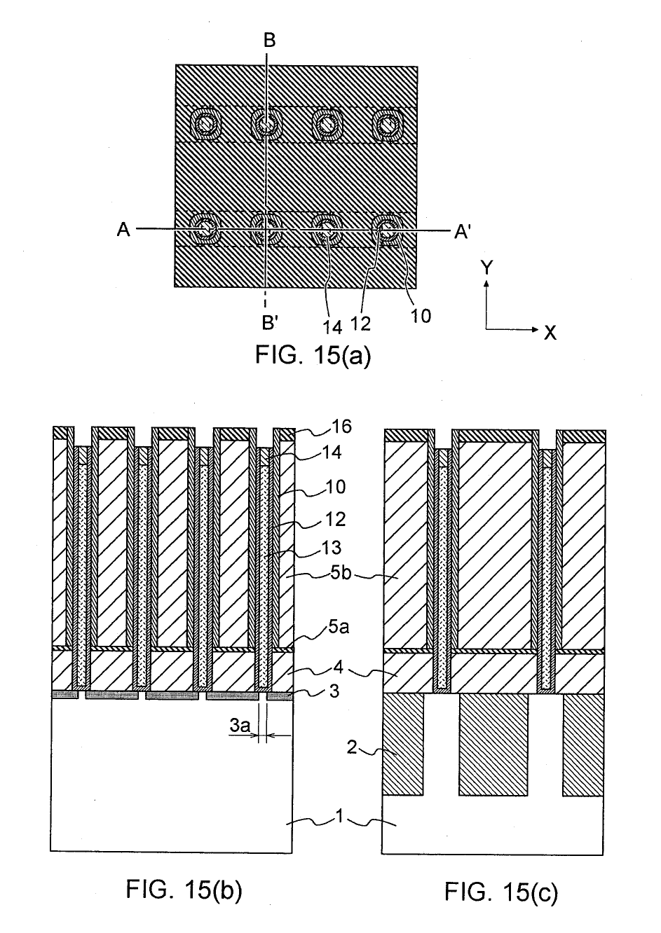

FIG. 14 illustrates a state where a CG electrode 10 is formed on a side surface of a hole 17 in a sidewall shape through the same processes as those illustrated in FIGS. 7 and 8 of embodiment 1, and a hole 11A is formed by etching an insulating layer 4 using the CG electrode 10 as a mask. Further, FIG. 15 illustrates a state where a NAND flash memory cell is formed by forming an insulating films 12 (tunnel insulating film and inter-gate electrode insulating film), an FG 13 and an embedded insulating layer 14 through the same processes as those illustrated in FIGS. 9 and 11 of embodiment 1. On the bottom surface of the gate electrode portion of the floating gate in which the gate electrode portion and the capacitor electrode portion are integrally formed, the pattern edge is formed with a curved shape of the smooth roundish corner. The gate electrode portion is above the slit 3a of the impurity diffusion layer 3 that is formed on the silicon substrate, and is arranged to stride across two impurity diffusion regions which are separated by the slit 3a. Further, the width of the channel region formed between the gate electrode portion and the slit is set to be narrower than the width of the active region formed in a line shape on the silicon substrate. As a method of rounding the corner of the pattern edge of the hole 17, for example, an etching process or a deposition process can be performed to round the corner of the pattern edge in addition to the lithographic process. For this reason, the pattern of the hole 17 can be formed using twice exposure using a photo mask having the line and space pattern arranged in the X direction and another photo mask having the line and space pattern arranged in the Y direction in addition to the once exposure using one photo mask having a hole pattern. Further, a sidewall film formed on the side surface of a core pattern can be used as a hard mask to form a hole pattern having a width equal to or smaller than the resolution limit.

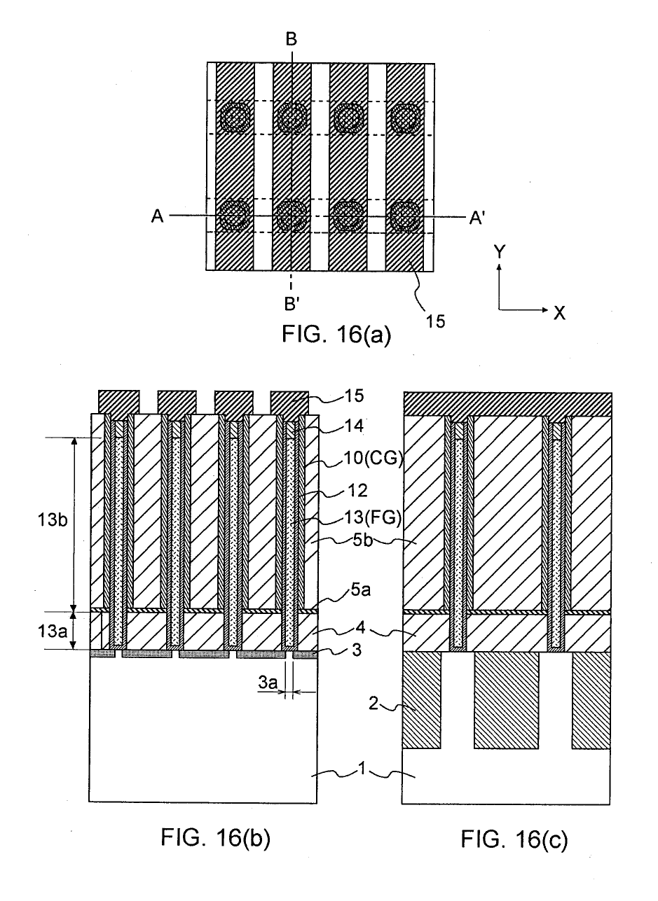

Finally, as illustrated in FIG. 16, after removing the hard mask layer 16, a conductive film for the control gate driving signal line 15 is formed and a wiring pattern that is extended in the Y direction is patterned to complete the NAND flash memory according to embodiment 2.

In the NAND flash memory according to embodiment 2, the plane shape of the bottom of the gate electrode portion of the floating gate in which the gate electrode portion and the capacitor electrode portion are integrally formed has a curved shape of the smooth roundish corner in the pattern edge. The bottom plane shape of the gate electrode portion includes a circle or an ellipse. Since the gate electrode portion and the capacitor electrode portion are integrally formed, the horizontal sectional shape of the capacitor electrode portion is similar to the bottom plane shape of the gate electrode portion. In the NAND flash memory cell, since the side surface of the capacitor electrode portion of the floating gate is smooth, it is possible to mitigate the local electric field concentration in the inter-gate electrode insulating film provided between the floating gate and the control gate, and thus the problem due to the local electric field concentration such as leak of charge injected into the floating gate can be suppressed.

Further, in the NAND flash memory according to embodiment 2, since the with of the gate electrode portion is set to be narrower than the width of the active region that is formed in a line shape on the silicon substrate, the bottom area of the gate electrode portion of the floating gate becomes small, and thus it is possible to maintain lower capacitance value between the floating gate and the channel region. That is, the height of the floating gate, which is required to obtain the capacitance ratio that is necessary for the operation of the NAND flash memory, can be reduced, and the process is facilitated. Further, the reduction of the bottom area of the gate electrode leads to the reduction of the planar occupation area of the floating gate, and thus the manufacturing cost is reduced. If the method of reading data written in the NAND flash memory cell is a method of detecting the on/off state of the NAND flash memory cell, it is necessary to arrange the gate electrode portion above the slit with striding across the two impurity diffusion layer region separated by the slit. In contrast, if the method of reading data written in the NAND flash memory cell is a method of detecting the conductance of the NAND flash memory cell, the line-shaped active region does not require the slit on the impurity diffusion layer in the NAND flash memory cell region. In either case, the gate electrode portion can be operated even if the width of the gate electrode portion is narrower than the width of the active region. In the former case, the region where the gate portion and the slit overlap each other becomes the channel region, and the width of the gate electrode portion becomes the width of the channel region.

According to the NAND flash memory in the related art, since the source/drain is formed through matching of their edges by introducing impurities into the surfaces of the adjacent silicon substrates using the formed control gate and floating agate as a mask, it is not possible to make the width of the gate electrode portion narrower than the width of the active region that is formed in a band shape on the silicon substrate as in the present invention. Further, it is necessary that the bottom plane shape of the gate electrode of the related art that is at least on the active region is rectangular. In contrast, in embodiment 2, since the source/drain region is first formed and then the floating gate and the control gate are formed later, the bottom plane shape of the gate electrode portion of the floating gate is not limited to a rectangular shape, but a circular or elliptical shape can be applied. Further, it is not required to form the gate electrode to cross from one end to the other end of the active region like a conventional gate electrode.

### Embodiment 3

Then, another modified example of the embodiment of the invention will be described.

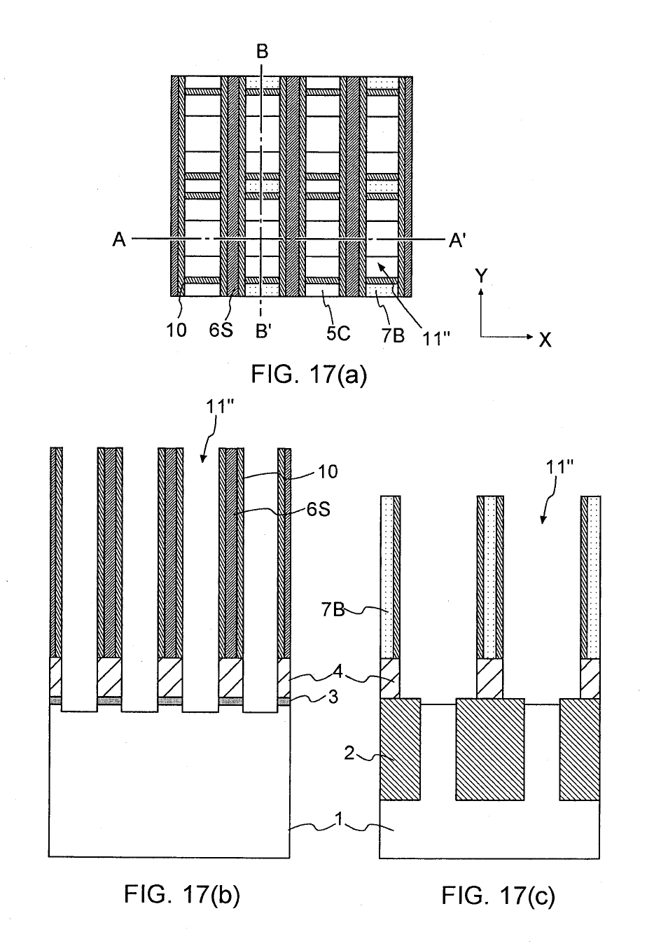

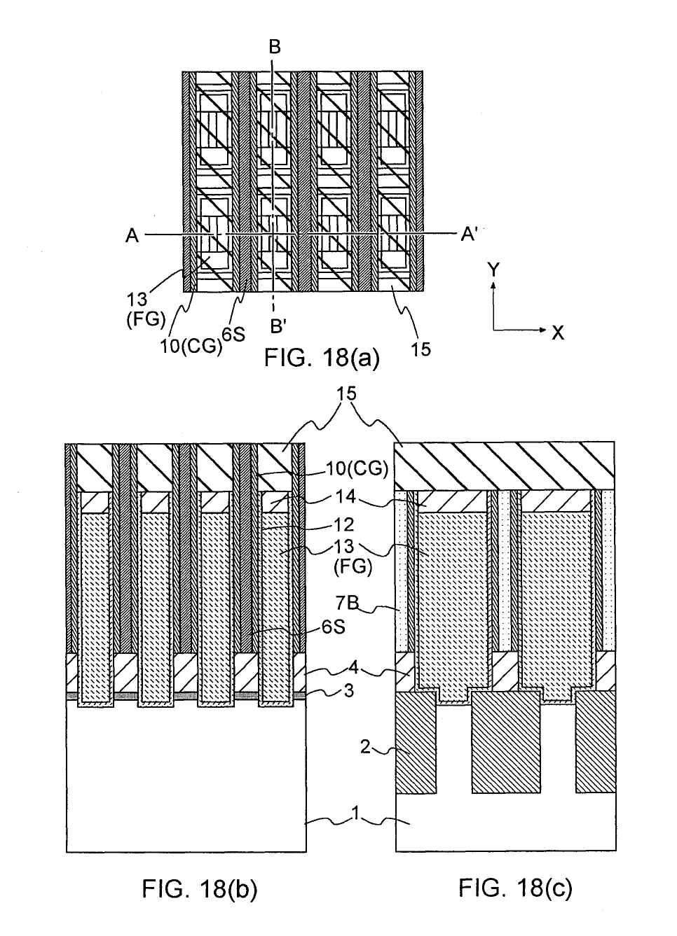

FIGS. 17 and 18 are views illustrating another modified example of a process for manufacturing a semiconductor device according to the invention. Among them, FIGS. 17(a) and 18(a) are plan views, FIGS. 17(b) and 18(b) are cross-sectional views taken along line A-A′, and FIGS. 17(c) and 18(c) are cross-sectional views taken along line B-B′.

As illustrated in FIGS. 17(a), 17(b), and 17(c), a groove is formed in an element isolation forming region of the surface of a p-type silicon substrate 1, and an element isolation region 2 is formed by embedding an insulating film such as a silicon oxide film. Then, a source/drain impurity diffusion layer 3 having a continuous line-shape is formed through ion-injecting of, for example, arsenic or the like into the surface of the active region that is positioned between the element isolation regions 2. Thereafter, after the same processes as the processes illustrated in FIGS. 2 to 8 of embodiment 1, the surface of the silicon substrate 1 is exposed by selectively removing the insulating layer 4 by etching using the CG electrode 10 as a mask. Subsequently, a groove is formed by etching the exposed silicon substrate 1 using the CG electrode 10 as a mask. At this time, the bottom of the groove is formed to reach a position that is deeper than the bottom of the source/drain impurity diffusion layer 3 so as to separate the source/drain impurity diffusion layer 3. Thereafter, through the same processes as the processes illustrated in FIGS. 9 to 12 of Embodiment 1, the NAND flash memory cell illustrated in FIGS. 18(a), 18(b), and 18(c) is completed.

The semiconductor device according to this embodiment includes a gate electrode portion of a floating gate that is formed inside a groove provided on the surface of the silicon substrate through an insulating film, and a pair of source/drain impurity diffusion layers. The floating gate is extended on the surface of the silicon substrate, and has a capacitor electrode portion integrally formed with the gate electrode portion. The capacitor electrode portion constitutes a capacitor together with a control gate laterally formed through the insulating film.

The method of manufacturing a semiconductor device according to this embodiment has features in that the surface of the silicon substrate in the floating gate forming region of the active region is selectively exposed, and then a groove is completed by further etching the exposed silicon substrate. That is, the source/drain impurity diffusion layer can be formed in self-aligned manner by separating the impurity diffusion layer previously formed in the line-shaped active region on the surface of the silicon substrate through a process of forming the groove. Thus, the impurities are introduced into the surface of the silicon substrate in advance, and the self-aligned source/drain impurity diffusion layer is formed at an edge of the gate electrode portion in the process of forming the floating gate later. By introducing in advance the impurities onto the surface of the silicon substrate, the problems in that the resistance of the source/drain impurity diffusion layer is heightened due to the fact that the impurities cannot be sufficiently introduced onto the surface of the silicon substrate in the NAND flash memory cell in the related art can be avoided.

Then, preferable configuration and operation of the NAND flash memory to which the present invention is applied will be briefly described.

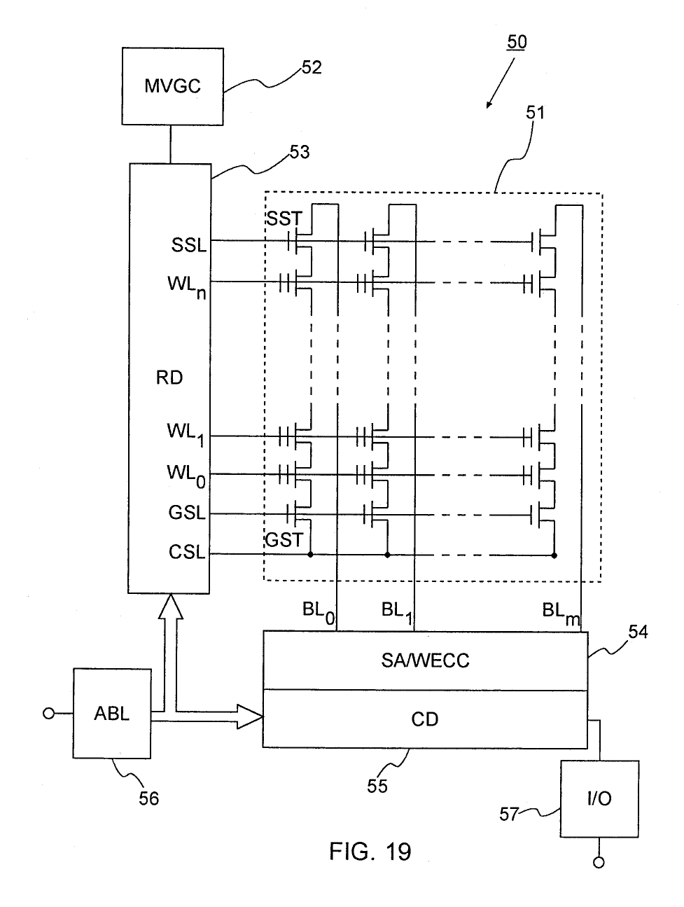

FIG. 19 is a block diagram illustrating the schematic configuration of a NAND flash memory 50 according to an embodiment of the present invention.

A NAND flash memory cell array includes a plurality of arranged NAND flash memory cell strings, and the NAND flash memory cell string includes a serial circuit of plural NAND flash memory cells, a string selection transistor SST connected to one end of the serial circuit, and a ground selection transistor GST connected to the other end of the serial circuit. One end of the serial circuit of the NAND flash memory cells is connected to a bit line BL, through the string selection transistor SST of which a gate is connected to a string selection line SSL, and the other end thereof is connected to a cell source line CSL through the ground selection transistor GST of which a gate is connected to the ground selection line GSL. The control gate of the NAND flash memory cell is connected to a word line WLₙ. A row decoder circuit (RD) 53 drives the string selection line SSL, the ground selection line GSL, a cell source line CSL, and word lines WL₀ to WLₙ on the basis of an external address that is output from an address buffer latch circuit (ABL) 56 that latches the external address input from an external address terminal. A multi-level voltage generation circuit (MVGC) 52 is a circuit that outputs plural discrete voltages that correspond to plural discrete data, and is connected to the row decoder circuit 53. A sense amplifier/write erase control circuit (SA/WECC) 54 is connected to bit lines BL₀ to BLₘ, and is connected to a column decoder circuit (CD) 55 receiving the external address output from the address buffer latch circuit (ABL) 56 and outputting a decoded signal and a data input/output (I/O) circuit 57 that is connected to an external data input/output terminal.

In an erase operation, electrons that are maintained in the floating gate are removed by connecting the control gate to ground potential and applying an erase voltage, for example, 19 V, to the memory cell substrate.

In a program operation, electrons are injected into the floating gate through tunnel current by connecting the memory cell substrate to ground potential and applying a program voltage to the control gate. As a result, a threshold voltage Vt of the flash memory cell transistor is increased.

In a read operation, a predetermined read voltage is applied to the control gate of the selected flash memory cell, and a voltage that makes all cells in an ON state is applied to the control gate of the unselected flash memory cell regardless of the program state of the floating gate. By determining whether current flows or not to a memory cell string selected by a sense amplifier connected to a bit line to which the selected memory cell string is connected, the program state of the floating gate of the selected flash memory is read out.

In this case, by determining whether current flows through dividing of a program operation into several program operations and performing reading operation in a state where a predetermined voltage V1 is applied to the control gate after the respective program operations, whether the threshold value of the selected memory cell reaches a predetermined value is tested, and the program state of the floating gate is verified. If the threshold value of the selected memory cell does not reach the predetermined value as a result of the test, a next program operation is performed, and by repeating this several times, the program operation is finished when the test result indicates that the threshold value of the selected memory cell reaches the predetermined value. In this case, if it is assumed that the potential of the floating gate corresponding to the voltage V1 that is applied to the control gate is Vt1, a program state of the floating gate in which the threshold value of the memory cell becomes Vt1 is obtained. In the same manner, by applying a voltage V2 that is different from V1 as a voltage that is applied to the control gate, a program state of the floating gate in which the threshold value of the corresponding selected memory cell becomes Vt2 is obtained. By doing this, it is possible to set plural program states with respect to one-bit flash memory cell. By storing multiple data, the floating gate of the one-bit flash memory cell is capable of setup to multiple program states corresponding to the multiple data.

In this embodiment, it is possible to set plural program states with respect to one-bit flash memory cell. Since by mounting a NAND flash memory cell according to this embodiment, the potential of the floating gate corresponding to the voltage that is applied to the control gate can be controlled with good precision regardless of the program state of the adjacent memory cell, a wide operating margin is obtained when setting plural program states with respect to one-bit flash memory cell.

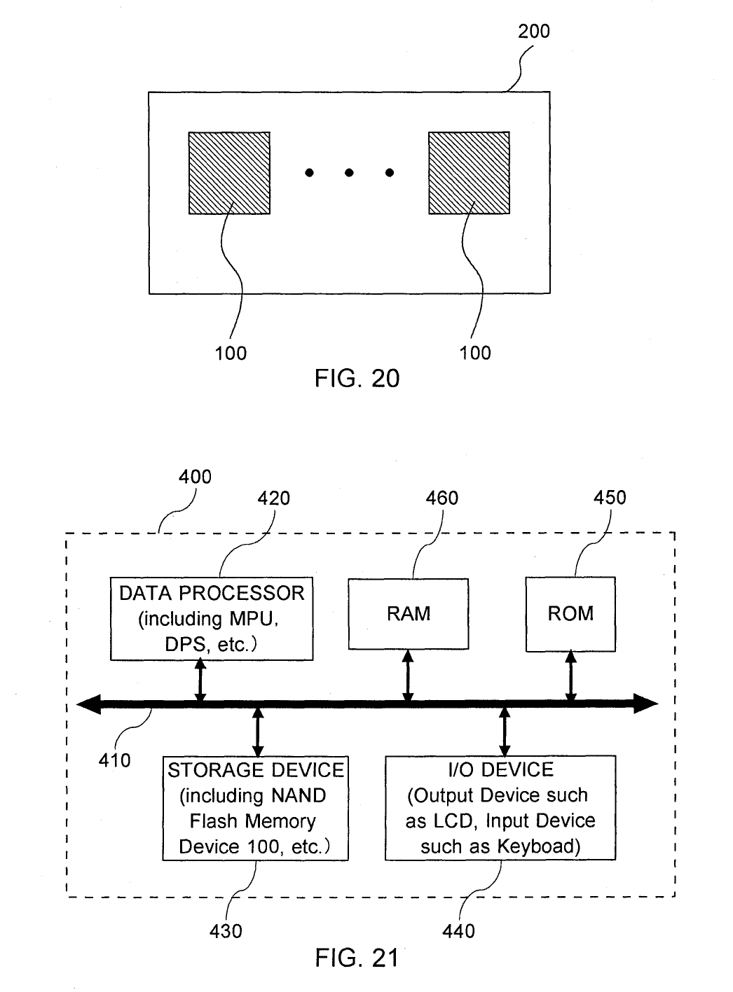

FIG. 20 is a schematic diagram illustrating the configuration of a memory card using a NAND flash memory according to the present invention.

A memory card 200 includes plural NAND flash memory devices 100 mounted thereon.

The NAND flash memory device 100, for example, includes a NAND flash memory 50 illustrated in FIG. 19, and has the NAND flash memory cells illustrated in FIG. 1 mounted thereon. In the same manner, it is possible to mount the NAND flash memory 50 according to the present invention on a multi-chip package.

FIG. 21 is a block diagram illustrating the configuration of a data processing system 400 using a NAND flash memory according to the present invention.

The data processing system 400 illustrated in FIG. 21 includes a data processor 420, and a storage device 430 including a NAND flash memory 50 illustrated in FIG. 19, a NAND flash memory device 100 or a memory card 200 illustrated in FIG. 20, which are connected together through a system bus 410. A data processor 420 can be a microprocessor (MPU) and a digital signal processor (DSP), but is not limited thereto. In FIG. 21, for simplicity, although the data processor 420 and the storage device 430 including the NAND flash memory device 100 are connected through one system bus 410, they can be connected by a local bus without passing the system bus 410. Further, the NAND flash memory 50 and/or the NAND flash memory device 100 can coexist in another semiconductor device (not illustrated) connected to the system bus 410. In the same manner, the NAND flash memory 50 and/or the NAND flash memory device 100 can coexist in the data processor 420.

In the data processing system 400 illustrated in FIG. 21, an I/O device 440, a read only memory (ROM) 450, and a random access memory (RAM) are connected to the system bus 410. However, they are not indispensable components. Further, the storage device 430 can include another storage device such as a hard disk.

While the present disclosure has been shown and described with reference to certain embodiments thereof, it will be understood by those skilled in the art that various changes in form and detail may be made therein without departing from the spirit and scope of the present disclosure, as defined by the appended claims.

What is claimed is:

1. A method of manufacturing a semiconductor device comprising:
forming a hole in a layer that is formed on a semiconductor material layer having one conduction type;
forming a first electrode through forming of a film comprising a conductive material on an inside wall of the hole;
forming a first insulating film on an inside wall of the first electrode; and
embedding a gate electrode in the hole in contact with the first insulating film.

2. The method of manufacturing a semiconductor device according to claim 1, wherein the gate electrode is in contact with a channel region formed on the semiconductor material layer through a second insulating film.

3. The method of manufacturing a semiconductor device according to claim 2, wherein after an impurity diffusion layer having the other conduction type is formed on the surface of the semiconductor material layer, the gate electrode is arranged so as to be in contact with a part of the impurity diffusion layer through the second insulating film.

4. The method of manufacturing a semiconductor device according to claim 3, wherein the impurity diffusion layer is separated into a first impurity diffusion layer and a second impurity diffusion layer through a slit, and the gate electrode is arranged to stride across the first and second impurity diffusion layers and the slit.

5. The method of manufacturing a semiconductor device according to claim 3, wherein the impurity diffusion layer is separated into a first impurity diffusion layer and a second impurity diffusion layer in a process of forming the impurity diffusion layer into a line-shape on the surface of the semiconductor material layer and in a process of forming a groove in a direction that crosses the line-shaped impurity diffusion layer and removing a part of the impurity diffusion layer in the groove, and the gate electrode is formed in the groove so as to be in contact with the first and second impurity diffusion layers through the second insulating film.

6. The method of manufacturing a semiconductor device according to claim 1, wherein the bottom plane shape of the gate electrode is a polygon with roundish corners.

7. The method of manufacturing a semiconductor device according to claim 1, wherein the bottom plane shape of the gate electrode is a circle or an ellipse.

8. The method of manufacturing a semiconductor device according to claim 2, further comprising simultaneously forming the first and second insulating films by forming an insulating film on an inside wall of the first electrode and a surface of the channel region that is formed on the semiconductor material layer.

9. The method of manufacturing a semiconductor device according to claim 8, further comprising exposing the channel region before the process of forming the insulating film.

10. The method of manufacturing a semiconductor device according to claim 1, further comprising:
forming a first material into plural line patterns extended in a first direction on the upper side of a surface of the semiconductor material layer;
forming isolation sidewall films by forming an insulating film on side surfaces of the line patterns;
embedding a second material in a concave portion that is positioned between the isolation sidewall films; and
forming linear patterns made of the first and second materials by selectively removing the first and second materials using a mask that is plural line patterns extended in a second direction different from the first direction,
wherein a hole that is positioned between the adjacent isolation sidewall films and between the adjacent linear patterns is formed.

11. The method of manufacturing a semiconductor device according to claim 10, further comprising:
etching back a gate electrode film formed in the hole to make the top of the gate electrode being lower than the top of the isolation sidewall film;
forming an embedded insulating layer by burying an insulating material in the concave portion that is positioned between the isolation sidewall films and on the gate electrode;
etching back the embedded insulating layer to make the top of the embedded insulating layer being lower than the top of the isolation sidewall film and exposing a part of the first electrode; and
forming a conductive line that is connected to the first electrode by burying an conductive material in the concave portion that is positioned between the isolation sidewall films and on the embedded insulating layer.

12. A semiconductor device comprising:
a gate electrode provided on a channel region in a semiconductor material layer having one conduction type through a second insulating film;
a capacitor electrode portion integrally formed with the gate electrode on the gate electrode; and
a first electrode laterally surrounding the capacitor electrode portion through a first insulating film.

13. The semiconductor device according to claim 12, wherein an impurity diffusion layer having the other conduction type is provided on the surface of the semiconductor material layer, and the impurity diffusion layer constitutes a source electrode and a drain electrode.

14. The semiconductor device according to claim 12, wherein the impurity diffusion layer is separated into a first impurity diffusion layer and a second impurity diffusion layer with a slit therebetween, and the gate electrode is arranged to stride across the first and second impurity diffusion layers and the slit.

15. The semiconductor device according to claim 12, wherein the bottom plane shape of the gate electrode is a polygon with roundish corners.

16. The semiconductor device according to claim 12, wherein the first insulating film and the second insulating film are comprised of the same material.

17. The semiconductor device according to claim 13, wherein a memory cell comprising the source electrode, the drain electrode, the gate electrode, and the first electrode is arranged in matrix, first electrodes of plural memory cells arranged in a first direction are connected to the same signal line; source electrodes and drain electrodes of plural memory cells arrange in a second direction are connected in series; one end thereof is connected to a bit line and the other end thereof is connected to a control line, respectively.

18. The semiconductor device according to claim 17, wherein the gate electrode is capable of setup to multiple program states corresponding to multiple data.

19. A memory card incorporated with plural semiconductor devices, wherein at least one of the semiconductor devices comprises:
a gate electrode provided on a channel region in a semiconductor material layer having one conduction type through a second insulating film;
a capacitor electrode portion integrally formed with the gate electrode on the gate electrode; and
a first electrode laterally surrounding the capacitor electrode portion through a first insulating film.

20. A data processing system comprising:
a storage device;
a data processor; and
a bus connecting the storage device and the data processor,
wherein at least one of the storage device and the data processor comprises:
a gate electrode provided on a channel region in a semiconductor material layer having one conduction type through a second insulating film;
a capacitor electrode portion integrally formed with the gate electrode on the gate electrode; and
a first electrode laterally surrounding the capacitor electrode portion through a first insulating film.
